(19) United States
(12) Patent Application Publication
(10) Pub. No.: US 2009/0282316 A1
(43) Pub. Date: Nov. 12, 2009

(54) Memory Access in Low-Density Parity Check Decoders

(75) Inventors: Srinivas Lingam, Dallas, TX (US); Yuming Zhu, Plano, TX (US); Arshad Ahmed, Dallas, TX (US); Shamshad Begum, Dubai (AE)

Correspondence Address: TEXAS INSTRUMENTS INCORPORATED, P O BOX 655474, M/S 3999, DALLAS, TX, 75265, US

(73) Assignee: TEXAS INSTRUMENTS INCORPORATED, Dallas, TX (US)

(21) Appl. No.: 12/436,756

(22) Filed: May 6, 2009

Related U.S. Application Data
(60) Provisional application No. 61/051,042, filed on May 7, 2008.

(51) Int. Cl. H03M 13/05; G06F 12/00; G06F 11/10

(52) U.S. Cl. 714/763; 711/154; 711/E12.001; 714/E11.032

(57) ABSTRACT

Low Density Parity Check (LDPC) decoder circuitry in which memory resources are realized as single-port memory. The decoder circuitry includes a single port memory for storing log-likelihood ratio (LLR) estimates of input node data states for individual rows of a parity check matrix. The decoder circuitry also includes multiple instances of single-port column sum memories, which store updated LLR estimates for each input node. In each case, the memory resources include logic circuitry that executes at least one write cycle and one read cycle to the memory within each decoder cycle. Because the decoder cycle time is much longer than the necessary memory cycle time, particularly in LDPC decoding, data can be written to and read from single-port memory resources in ample time for the decoding operation.

### CROSS-REFERENCE TO RELATED APPLICATIONS

This application claims priority, under 35 U.S.C. §119(e), of U.S. Provisional Application No. 61/051,042, filed May 7, 2008, which is incorporated herein by this reference.

### STATEMENT REGARDING FEDERALLY SPONSORED RESEARCH OR DEVELOPMENT

Not applicable.

### BACKGROUND OF THE INVENTION

This invention is in the field of error detection and correction coding and decoding of communicated digital data streams. Embodiments of this invention are more specifically directed to the construction of memory resources, and the manner of accessing those memory resources, in the decoding of such data streams.

High-speed data communication services, for example in providing high-speed Internet access, have become a widespread utility for many businesses, schools, and homes, and are implemented by an array of technologies. In the wireless realm, recent advances in wireless communications technology have enabled localized wireless network connectivity according to the IEEE 802.11 standard to become popular for connecting computer workstations and portable computers to a local area network (LAN), and typically through the LAN to the Internet. Broadband wireless data communication technologies, for example those technologies referred to as “WiMAX” and “WiBro”, and those technologies according to the IEEE 802.16d/e standards, have also been developed to provide wireless DSL-like connectivity in the Metro Area Network (MAN) and Wide Area Network (WAN) context. Multiple-input-multiple-output (MIMO) communication techniques, which involve multiple signal paths between the transmitter and receiver, provide improved error rates by using the benefits of spatial diversity to recover the transmitted data. Wired communications technologies include a wide range of modulation and protocols that provide high data rate communications over various physical facilities such as fiber optic lines, coaxial cable, and copper wire (Ethernet, twisted-pair, etc.).

In addition to these client-based communications applications, modern high data-rate “backhaul” communications occur over the intermediate links between the network core and the facilities at the network “edges”. An example of a “backhaul” link is that between a cellular telephone tower and the central office of the cellular service provider. These backhaul links carry all of the communications currently supported by that specific tower, in both directions, and as such support very high data rate communications.

Digital television is another popular use of digital data communications technologies, considering that digital data is broadcast over satellite, coaxial cable, and now even fiber optic communications facilities. Wireless communication of television content is also beginning, for example as communicated to portable electronic devices over the cellular network or via WiFi.

A problem that is common to all data communications technologies is the corruption of data by noise. As is fundamental in the art, the signal-to-noise ratio for a communications channel is a degree of goodness of the communications carried out over that channel, as it conveys the relative strength of the signal that carries the data (as attenuated over distance and time), to the noise present on that channel. These factors relate directly to the likelihood that a data bit or symbol as received differs from the data bit or symbol as transmitted. This likelihood of a data error is reflected by the error probability for the communications over the channel, commonly expressed as the Bit Error Rate (BER) ratio of errored bits to total bits transmitted. In short, the likelihood of error in data communications must be considered in developing a communications technology. Techniques for detecting and correcting errors in the communicated data must be incorporated for the communications technology to be useful.

Error detection and correction techniques based on redundant coding are typically implemented in many of these communications environments. In general, redundant coding inserts bits into the transmitted data stream that do not add any additional information, but that indicate, on decoding, whether an error is present in the received data stream. More complex codes provide the ability to deduce the true transmitted data from a received data stream even if errors are present.

Many types of redundant error correction codes have been developed. One type of code simply repeats the transmission, for example by sending the payload followed by two repetitions of the payload, so that the receiver deduces the transmitted data by applying a decoder that determines the majority vote of the three transmissions for each bit. While this simple redundant approach can correct many (but not necessarily all) errors, the payload data rate is greatly reduced. In addition, this simple majority-vote approach leaves a predictable likelihood that two of three bits are in error, resulting in an erroneous majority vote despite the useful data rate having been reduced to one-third. More efficient approaches, such as Hamming codes, have been developed toward the goal of reducing the error rate while maximizing the data rate.

The well-known Shannon limit provides a theoretical bound on the optimization of decoder error as a function of data rate. The Shannon limit provides a metric against which codes can be compared, both in the absolute sense and also relative to one another. Since the time of the Shannon proof, modern data correction codes have been developed to more closely approach the theoretical limit. An important class of these conventional codes includes “turbo” codes, which encode the data stream by applying two convolutional encoders. One of these convolutional encoders encodes the datastream as given, while the other encodes a pseudo-randomly interleaved version of the data stream. The results from the two encoders are interwoven to produce the encoded data stream.

Another class of known redundant codes are the Low Density Parity Check (LDPC) codes. The fundamental paper describing these codes is Gallager, Low-Density Parity-Check Codes, (MIT Press, 1963), monograph available at http://www.inference.phy.cam.ac.uk/mackay/gallager/papers/. In these codes, a sparse matrix H defines the code, with the encodings c of the payload data satisfying:

Hc=0 (1)

over Galois field GF(2). Each transmitted encoding c consists of the source message cᵢ combined with the corresponding parity check bits cₚ for that source message cᵢ. The signal vector r=c+n is received by the receiving network element, where n is the noise added by the channel. Because the decoder at the receiver also knows matrix H and because Hc=0, the decoder can compute a vector z=Hr:

z=Hr=Hc+Hn=Hn (2)

The decoding process thus involves finding the sparsest vector x that satisfies:

Hx=z (3)

over GF(2). This vector x becomes the best guess for noise vector n, which can be subtracted from the received signal vector r to recover encodings c, from which the original source message cᵢ is recoverable.

There are many known implementations of LDPC codes. Some of these LDPC codes have been described as providing code performance that approaches the Shannon limit, as described in MacKay et al., “Comparison of Constructions of Irregular Gallager Codes”, Trans. Comm., Vol. 47, No. 10 (IEEE, October 1999), pp. 1449-54, and in Tanner et al., “A Class of Group-Structured LDPC Codes”, ISTCA-2001Proc. (Ambleside, England, 2001).

In theory, the encoding of data words according to an LDPC code is straightforward. Given enough memory or small enough data words, one can store all possible codewords in a lookup table, and look up the code word in the table according to the data word to be transmitted. But modern data words to be encoded are on the order of 1 kbits and larger, rendering lookup tables prohibitively large and cumbersome. Accordingly, algorithms have been developed that derive codewords, in real time, from the data words to be transmitted. A straightforward approach for generating a codeword is to consider the n-bit codeword vector c in its systematic form, having a data or information portion cᵢ and an m-bit parity portion cₚ such that c=(cᵢ |cₚ). Similarly, parity matrix H is placed into a systematic form H_{sys}, preferably in a lower triangular form for the m parity bits. In this conventional encoder, the information portion cᵢ is filled with n-m information bits, and the m parity bits are derived by back-substitution with the systematic parity matrix H_{sys}. This approach is described in Richardson and Urbanke, “Efficient Encoding of Low-Density Parity-Check Codes”, IEEE Trans. on Information Theory, Vol. 47, No. 2 (February 2001), pp. 638-656. This article indicates that, through matrix manipulation, the encoding of LDPC codewords can be accomplished in a number of operations that approaches a linear relationship with the size n of the codewords. However, the computational efficiency in this and other conventional LDPC encoding techniques does not necessarily translate into an efficient encoder hardware architecture. Specifically, these and other conventional encoder architectures are inefficient because they typically involve the storing of inverse matrices, by way of which the parity check of equation (1), or a corollary, is solved in the encoding operation.

By way of further background, U.S. Pat. No. 7,178,080 B2, issued Feb. 13, 2007, and U.S. Pat. No. 7,139,959 B2, issued Nov. 21, 2006, commonly assigned herewith and incorporated herein by this reference, describe a family of structured irregular LDPC codes, and decoding architectures for those codes. The quasi-cyclic structure of this family of LDPC codes can also provide efficiencies in the hardware implementation of the encoder, as described in U.S. Pat. No. 7,162,684 B2, issued Jan. 9, 2007, commonly assigned herewith and incorporated herein by this reference. The encoder and encoding method that are described in this U.S. Pat. No. 7,162,684 B2 follow a generalized approach, and are capable of handling such complications as row rank deficiency.

By way of still further background, U.S. Pat. No. 7,506,238 B2, commonly assigned herewith and incorporated herein by this reference, describes constraints on this family of structured irregular LDPC codes that enable recursive, and efficient, encoding of communications.

By way of still further background, U.S. patent application Ser. No. 11/284,929, published as U.S. Patent Application Publication No. US 2006/0123277 A1, commonly assigned herewith and incorporated herein by this reference, describes the shortening and puncturing of systematic codewords, and more specifically describes the selection of the number of shortened bits and the number of punctured bits from a given codeword length and code rate, for encoding according to a different selected codeword length. The approach described in this U.S. Patent Application Publication No. US 2006/0123277 A1 is believed to be particularly useful in connection with broadband wireless MAN communications according to the IEEE 802.16 standard.

By way of still further background, U.S. patent application Ser. No. 11/550,662, published as U.S. Patent Application Publication No. US 2007/0086539 A1, commonly assigned herewith and incorporated herein by this reference, describes LDPC error correction coding in the MIMO context, and a particular LDPC code arrangement that provides excellent error rate performance for that application.

The above-incorporated U.S. Patents and Patent Application Publications describe decoder hardware implementations that are well-suited for LDPC decoding. FIG. 1a illustrates one example of such decoder hardware, as used to execute the “belief propagation” LDPC decoding algorithm. As described, for example, in the above-incorporated U.S. Patent Application Publication No. US 2007/0086539 A1, the LDPC decoding process fundamentally involves an iterative two-step process:
1. Estimate a value Rₘⱼ for each of the j input nodes in each of the m rows of the checksum, using the current probability values from the other input nodes, and setting the result of the checksum for row m to 0; and
2. Update a sum L(qⱼ) for each of the j input nodes from a combination of Rₘⱼ values for the same column.
   The iterations continue until a termination criterion is reached. A preferred termination criteria is the earlier of (i) evaluation of the matrix operation H·c=0 (mod 2), using “hard” decisions from the LLRs L(qⱼ) as the codeword vector c, and (ii) completion of a specified number of iterations.

As shown in FIG. 1a, this LDPC decoder includes two-port random access memory (RAM) 2, which stores the Rₘⱼ estimates that are derived within each iteration of the belief propagation. Each Rₘⱼ value corresponds to an estimate of the log-likelihood-ratio (LLR) of the data state of an input node j, as derived from the values of the other input nodes participating in the row m of the parity check matrix (i.e., not using the value of input node j itself in this estimate). These R estimates for the other input nodes are the most recent estimates generated by parity check update blocks 6, and the Rₘⱼ value being evaluated will be used in the next decoding iteration. Memory 2 is conventionally implemented as a two-port memory, in that updated Rₘⱼ estimates for use in the next iteration are written into memory 2 in the same decoder cycle as Rₘⱼ values from a previous iteration (usually for a different row or rows) are read from memory 2.

While parity check update block 6 can operate on a single row m of the parity check matrix in a single pass, parity check update block 6 can include multiple instances of the corresponding logic, each associated with a row of the parity check matrix, as described in U.S. Patent Application Publication No. US 2007/0086539 A1. The number of parallel parity check update circuits can vary from one to any desired number, depending on the particular application and available resources.

To accomplish this parity check sum update, two-port RAM 2 has an output coupled to a subtracting input of an instance of parallel adders 4. Each one of parallel adders 4 performs a subtraction:

L(qₘⱼ)=L(qⱼ)−Rₘⱼ

for each column j of each row m of the checksum, effectively updating the estimate of the probability of the input node value, excluding the contribution to the estimate for each row from the row itself. These updated “extrinsic” value estimates L(qₘⱼ) are then applied to parity check update function 6, which update the estimates Rₘⱼ for each of the parity check nodes, producing the values Rⁱ⁺¹ₘⱼ (for use in the next, i+1, iteration) that are stored in two-port memory 2.

The construction of parity check update function 6 is described in the above-incorporated U.S. Pat. No. 7,178,080 B2. As described therein, each incoming extrinsic value estimate L(qₘⱼ) from an adder within parallel adder 4 is applied to a look-up table to evaluate a Ψ function for a corresponding row m of the parity check matrix, and the values Ψ(L(qₘⱼ)) over all of the columns participating in that row m are summed. That resulting sum is then applied to a corresponding one of multiple adders within parity check update function 6, each such adder associated with one of the columns j that contribute to current row m, with that adder subtracting the corresponding LUT output, which is the column's own contribution, from the overall sum. These adders present a set of amplitude values Aₘⱼ, each associated with one of the columns j participating in this row; zero-valued columns j do not participate in the row, and thus do not have an amplitude value Aₘⱼ. Also within parity check update function 6, the Ψ function is applied to these amplitude values Aₘⱼ, with a sign (+/−) applied to the result according to a logical odd/even determination of the number of negative probabilities for the corresponding column, excluding each column's own contribution. Updated estimate values Rⁱ⁺¹ₘⱼ are generated by parity check update function 6 for iteration i+1 in this manner, and are returned to two-port memory 2.

Of course, variations of this parity check update approach, and other alternative parity check update approaches, may also be realized within parity check update circuit 6, depending on the available circuitry and performance of the specific implementation.

In addition, parity check update function 6 presents its outputs (the updated estimate values Rⁱ⁺¹ₘⱼ) to a corresponding one of parallel adders 7. Parallel adders 7 also each receive, at another input, outputs of corresponding ones of parallel adders 4, which communicate the per-row LLR probability estimates values L(qₘⱼ) that were used by parity check update function 6. Parallel adders 7 thus calculate the updated log likelihood ratio (LLR) estimates L(qⱼ) for each input node, according to:

L(qⱼ)=L(qₘⱼ)+Rₘⱼ

These updated values L(qⱼ) are then forwarded to forward router circuitry 8f. If desired, parallel adders 7 can also include sign change detection operations, in which the sign bits of the LLR estimates L^{h}(qⱼ) for each input node from the previous subset are compared with the sign bits of the updated LLR estimates L^{h+1}(qⱼ) for those input nodes from the current subset, to determine whether a difference is present for any column j. This determination of a difference in sign can be used in determining whether the decoding has converged to a valid result.

Router circuitry 8f is a bank of multiplexers and demultiplexers that forwards the appropriate estimate values L(qⱼ) to a corresponding one of corresponding column update circuits 9. Column update circuits 9 are effectively accumulators, implemented to include one or more two-port memories, by way of which current values of the LLRs of the input nodes are maintained from iteration to iteration. In the example described in the above-incorporated U.S. Patent Application Publication No. US 2007/0086539 A1, the number of column update circuits 9 and associated two-port memories depends upon the maximum number of groups of block columns of macro matrix H_{M} in the particular code. Column update circuits 9 also have inputs at which the received input node data values are applied, prior to the first iteration of the belief propagation.

Column update circuits 9 present outputs to reverse router circuitry 8r, which is a bank of multiplexers and demultiplexers that re-arrange the current LLR values generated by column update circuits 9, so that those new values are applied to the proper one of parallel adders 4, as the minuends in that subtraction. These values indicate the current column or bit update values L(qⱼ) that are to be applied in the current check sum update performed by check sum update function 6. The outputs of column update circuits 9 are also applied by reverse router circuitry 8r to parity check function 11, which performs a slicing function on these estimates, and after converting these values to “hard” decisions, determines whether the parity check equation is satisfied by the current estimates for each row of parity check matrix H.

As evident from FIG. 1a, the column sum memories within column update circuits 9 both receive input values for storage and also present values for output, within each iteration. Conventional LDPC decoders thus realize the memories within column update circuits 9 as two-port memories, so that data can be written to the memories, and read from the memories, in the same cycle. Such two-port memories, in conventional LDPC decoders, also require logic circuitry to ensure that there is not a data conflict or loss of coherency that can result if the write and read operations are being performed to the same memory locations (i.e., a “write-before-read” error).

By way of further background, in the example described in the above-incorporated U.S. Patent Application Publication No. US 2007/0086539 A1, the LDPC code itself is constrained to ensure that, when a given input node LLR value L(qⱼ) has just been updated, that same input node LLR value L(qⱼ) will not be updated from other rows in that subset (or block row), and therefore need not be protected from overwriting during the processing of that same subset (or block row). By treating the LDPC code as a layered code, in which the parity check matrix H is considered as multiple subsets, each subset corresponding to a group of matrix rows in which each column has a weight of at most one, and in which the decoding operation operates on one subset at a time, single column sum memories within column update circuits 9 can be used. Again, however, these column sum memories are typically implemented as dual-port memories; according to this layered code approach, however, address conflicts are guaranteed to be avoided.

FIG. 1b illustrates the relative timing of decoder cycles, and read and write cycles to dual-port memory resources. Decoder cycles k through k+2 are shown in FIG. 1b, and correspond to the time required for each of the decoder “stages” to execute. For example, within one decoder cycle, one parity check sum update operation is performed by parity check update function 6, and one column update is performed by column update circuits 9. Because each of RAM 2 and the column sum memories within column update circuits 9 are realized as two-port memory, each of these memory resources execute, within each decoder cycle, a read operation to provide contents to the parity check and column sum update operations, and also a write operation to receive updated estimates, as the case may be. The use of dual-port memory in conventional LDPC decoders allows these write and read operations to be performed simultaneously, avoiding latency delays.

Because of this dual-port construction, however, conventional implementations of LDPC decoders require substantial chip area to realize the necessary memories for the R values, and the memories for the column update values. This chip area is somewhat exacerbated because these memories are of relatively small capacity. For example, a typical size for two-port memory 2 (for the R values) is 86 rows by 960 columns (or eight banks of 86 rows by 120 columns) of two-port static random access memory (SRAM); a typical size for the column sum memories in column update circuits 9 is thirty-two banks of 43 row by 60 column two-port SRAM. As known in the art, small memories are inherently inefficient, from the standpoint of bits per unit chip area, even when constructed as single-port memories, because of the overhead required for the peripheral circuitry (decoders, sense amplifiers, etc.). Small two-port memories especially “blow out” the chip area required, with some small two-port memories requiring more than twice the chip area as single-port memories of the same memory capacity. Worse yet, the number of memories required for an LDPC decoder increases with increasing throughput, typically because the LDPC code becomes more complex in attempts to reach the Shannon limit.

By way of further background, the above-incorporated U.S. Pat. No. 7,178,080 B2 describes an approach in which two column sum memories are provided in each column update circuit in an LDPC decoder. By providing these two memories, updates for each column are stored in one column sum memory while the other column sum memory is made available for forwarding the previously updated results. As such, the column sum memory roles alternate read and write operations, in ping-pong fashion. Of course, the necessity of providing two memories for each column update unit, even if such memories are single-port memories, is not an appreciable improvement from the standpoint of chip area over the two-port memory implementations.

As a result, it has been observed that up to as much as one-half of the chip area required to realize a conventional LDPC decoder is consumed by the memory resources. Memory chip area is thus a large factor in the manufacturing cost of an integrated circuit for data communications, including such an LDPC decoder.

### BRIEF SUMMARY OF THE INVENTION

Embodiments of this invention provide decoder circuitry operating according to belief propagation error detection and correction codes, and methods of operating the same, in which the chip area required for its memory resources is substantially reduced relative to conventional decoders.

Embodiments of this invention provide such circuitry and methods in which the improved chip area efficiency is attained without adversely impacting performance of the decoder operation.

Embodiments of this invention provide such circuitry and methods in which higher performance decoding can be realized for a given cost in chip area as compared with conventional decoders.

Other objects and advantages of this invention will be apparent to those of ordinary skill in the art having reference to the following specification together with its drawings.

The present invention may be implemented into an integrated circuit containing circuitry or functionality for decoding received data streams according to a belief propagation decoder algorithm, such as used in connection with Low Density Parity Check (LDPC) codes. At least one memory resource in that circuitry is realized by way of single-port memory, in combination with logic circuitry that controls the memory to execute a single write and a single read within each decoder cycle. The memory cycle times are each about one-half the cycle time of the decoder cycle, the addresses to which the read and write accesses are made within the same cycle are independent from one another.

### BRIEF DESCRIPTION OF THE SEVERAL VIEWS OF THE DRAWING

FIG. 1a is an electrical diagram, in block form, of conventional LDPC decoder circuitry.

FIG. 1b is a timing diagram illustrating the operation of the conventional circuitry of FIG. 1a.

FIG. 2 is a data flow diagram illustrating data communications according to an embodiment of the invention.

FIG. 3 is an electrical diagram, in block form, of the construction of a communications receiver constructed according to an embodiment of the invention.

FIG. 4a is an electrical diagram, in block form, of the construction and functional operation of an LDPC decoder constructed according to an embodiment of the invention.

FIG. 4b is an electrical diagram, in block form, of the construction of column sum update circuitry in the LDPC decoder of FIG. 4a, according to an embodiment of the invention.

FIG. 5 is an electrical diagram, in block form, of the construction of a column sum update circuit in the LDPC decoder of FIG. 4a, according to that embodiment of the invention.

FIG. 6 is an electrical diagram, in block form, of a memory constructed according to an embodiment of the invention, as used in the LDPC decoder of FIG. 4a.

FIGS. 7a and 7b are timing diagrams illustrating the operation of embodiments of the invention.

### DETAILED DESCRIPTION OF THE INVENTION

The present invention will be described in connection with its preferred embodiment, namely as implemented into decoder circuitry applying a Low Density Parity Check (LDPC) error detection and correction code, because it is contemplated that this invention will be especially beneficial when used in such an application. However, it is contemplated that this invention can be used to great benefit in other applications, particularly in decoders operating according to other belief propagation or similarly iterative techniques, such as turbo decoding. Accordingly, it is to be understood that the following description is provided by way of example only, and is not intended to limit the true scope of this invention as claimed.

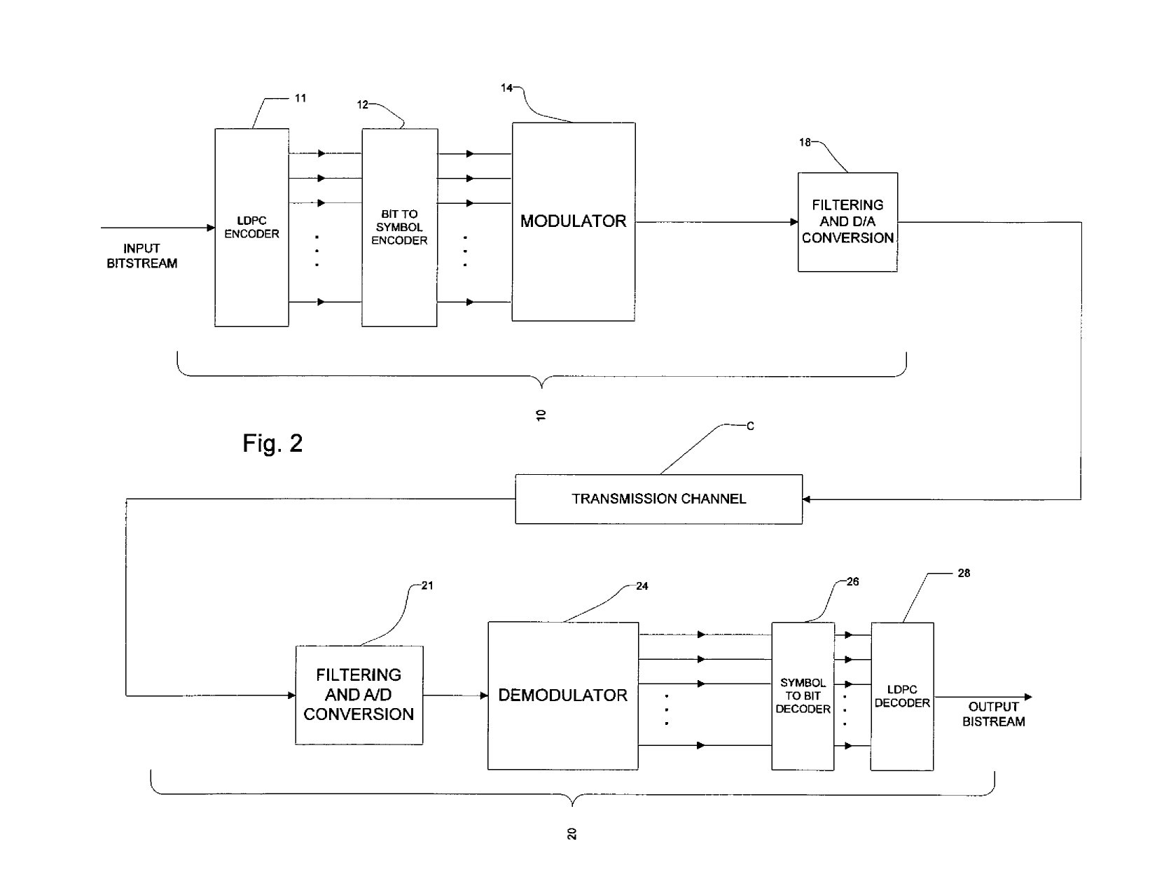

FIG. 2 functionally illustrates an example of a somewhat generalized communication system into which the preferred embodiment of the invention is implemented, for purposes only of providing context to embodiments of the invention. The illustrated system is somewhat generic in the sense that it represents encoded communications according to a wide variety of technologies. For example, as described in the above-incorporated U.S. Pat. No. 7,139,959 B2, this system can correspond to an OFDM modulation arrangement, as useful in wireless communications as contemplated for IEEE 802.11 wireless networking. The system of FIG. 2 is also applicable to communications involved in a “backhaul” link of a telecommunications network between a facility at the “edge” of the network and a core of the network, for example between a cellular telephone tower and the central office of the cellular service provider. The system of FIG. 2 is also applicable to digital television communications, over a facility such as a satellite link, coaxial cable facility, fiber optic, etc., in which a set-top box or digital television decodes the digital transmission of television content. This system can also be used in myriad other data communications applications.

In this generalized system of FIG. 2, only one direction of transmission over transmission channel C is illustrated, namely from transmitter 10 to receiver 20. It will of course be understood by those skilled in the art that, in some applications, data will also be communicated in the opposite direction, in which case receiver 20 will be realized in the form of a transceiver, and will be transmitting data over channel C, to transmitter 10, which is also in the form of a transceiver.

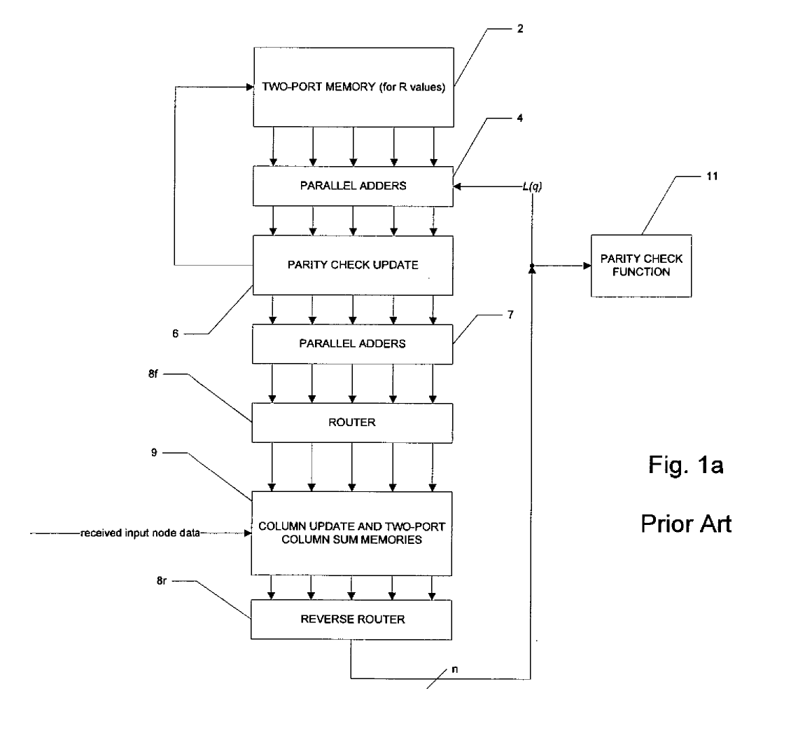

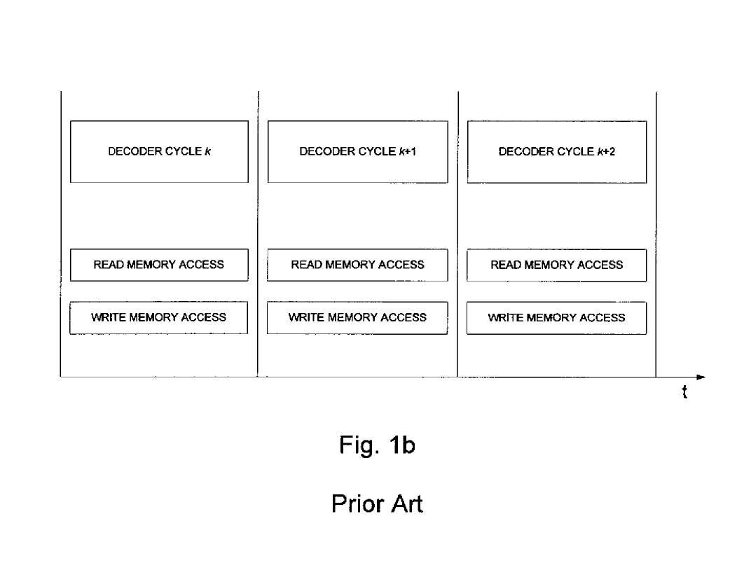

As shown in FIG. 1a, transmitter 10 receives an input bitstream that is to be transmitted to receiver 20. The input bitstream may be generated by a computer at the same location (e.g., the central office) as transmitter 10, or coupled to transmitter 10 over a computer network, in the Internet sense. Typically, this input bitstream is a serial stream of binary digits, in the appropriate format as produced by the data source.

The input bitstream is received by LDPC encoder function 11, according to this embodiment of the invention. LDPC encoder function 11 digitally encodes the input bitstream by applying a redundant code for error detection and correction purposes. According to this embodiment of the invention, the redundant LDPC code applied by encoder function 11 is selected in a manner that facilitates implementation and performance of the corresponding decoder in receiver 20. An example of encoder function 11 according to the preferred embodiment of the invention is described in the above-incorporated U.S. Pat. No. 7,162,684 B2, although any conventional encoder arrangement or method can be used. In general, the coded bits include both the payload data bits and corresponding code bits, so that the application of the codeword (payload plus code bits) to the sparse LDPC parity check matrix equals zero for each parity check row. After application of the LDPC code, bit to symbol encoder function 12 groups the incoming bits into symbols having a size, for example, ranging up to as many as fifteen bits, as appropriate for modulation. For example, the symbols output by bit-to-symbol encoder 12 can correspond to Quadrature Amplitude Modulation (QAM) symbol points in a selected QAM “constellation”, as known in the art.

Modulator 14 corresponds to conventional circuitry for modulating the encoded symbols generated by LDPC encoder 11 and bit-to-symbol encoder 12 into a time-varying signal stream suitable for transmission over channel C. The particular modulation scheme applied by modulator 14, and thus the construction and operation of modulator 14, will depend on the communications protocol to be used. For example, if the communications are to be carried out according to Discrete Multitone Modulation (DMT), modulator 14 will be implemented as an inverse Discrete Fourier Transform (IDFT) function, which associates each input symbol with one subchannel in the transmission frequency band, generates a corresponding number of time domain symbol samples according to an inverse Fourier transform, and converts those time domain symbol samples into a serial sequence of symbol values representative of the sum of a number of modulated subchannel carrier frequencies. Modulator 14 can be constructed and operate according to other modulation approaches, as known in the art, according to the desired communications scheme. In any case, those skilled in the art having reference to this specification will readily recognize that functions 11, 12, 14 may be carried out by custom logic, or by way of program instructions executed by a digital signal processor (DSP).

Filtering and conversion function 18 then processes the datastream for transmission. Function 18 applies the appropriate digital filtering operations, such as interpolation to increase sample rate and digital low pass filter for removing image components, for the transmission. The digitally-filtered datastream signal is then converted into the analog domain and the appropriate analog filtering is then applied to the output analog signal, prior to its transmission.

The output of filter and conversion function 18 is then applied to transmission channel C, for forwarding to receiver 20. The transmission channel C will of course depend upon the type of communications being carried out, whether wireless, coaxial or fiber optic, satellite, or the like. This transmitted signal is received by receiver 20, which, in general, reverses the processes of transmitter 10 to recover the information of the input bitstream.

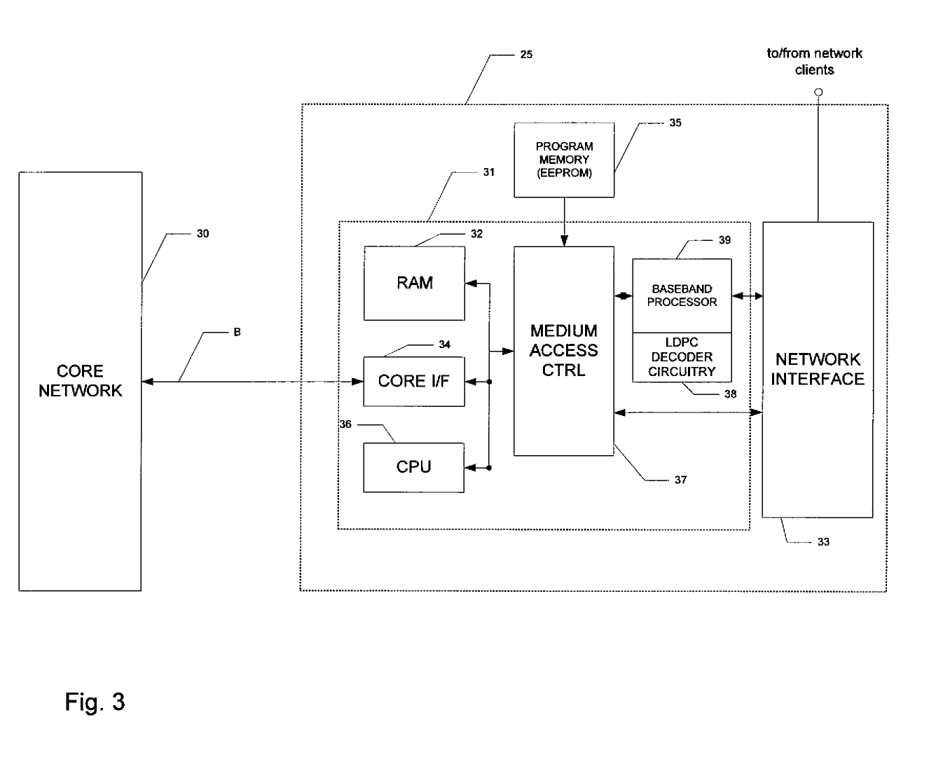

FIG. 3 illustrates an exemplary construction of receiver 20, in the form of a backhaul transceiver that manages communications between client devices and core network 30. Transceiver 25 is coupled to core network 30 by way of a corresponding bus B. Core network 30 corresponds to the cellular telephone central office switching gear and the like; of course, the particulars of core network 30 will vary with the particular application, and indeed can correspond to such things as a host personal computer or workstation, a digital television or set-top box, or the like, depending on the application. In the example of FIG. 2, transceiver 25 may correspond to a network adapter or installation that is physically realized within a backhaul system.

Transceiver 25 in this example includes processor 31, which is bidirectionally coupled to bus B on one side, and to network interface 33 on its other side. Network interface 33, which may be realized by conventional RF, microwave, or other circuitry known in the art, performs the analog demodulation, amplification, and filtering of signals received from the network channel and the analog modulation, amplification, and filtering signals to be transmitted over the network channel. According to this architecture, processor 31 includes embedded central processing unit (CPU) 36, for example realized as a reduced instruction set (RISC) processor, for managing high level control functions within processor 31. For example, embedded CPU 36 manages host interface 34 to directly support the appropriate physical interface to bus B and host system 30. Local RAM 32 is available to embedded CPU 36 and other functions in processor 31 for code execution and data buffering. Medium access controller (MAC) 37 and baseband processor 39 are also implemented within processor 31 according to embodiments of the invention, for generating the appropriate packets for wireless communication, and providing encryption and decryption functionality as appropriate. Program memory 35 is provided within transceiver 25, for example in the form of electrically erasable/programmable read-only memory (EEPROM), to store the sequences of operating instructions executable by processor 31, including LDPC decoding sequences according to embodiments of the invention, which will be described in further detail below. Also included within transceiver 25 are other typical support circuitry and functions that are not shown, but that are useful in connection with its particular operation.

According to the preferred embodiments of the invention, LDPC decoding is embodied in specific custom architecture hardware associated with baseband processor 39, and shown as LDPC decoder circuitry 38 in FIG. 3. LDPC decoder circuitry 38 is custom circuitry for performing the coding and decoding of transmitted and received data packets according to the preferred embodiments of the invention. Examples of the particular construction of LDPC decoder circuitry 38 according to the preferred embodiment of this invention will be described in further detail below.

Alternatively, it is contemplated that baseband processor 39 itself, or other computational devices within transceiver 25, may have sufficient computational capacity and performance to implement the decoding functions described below in software, specifically by executing a sequence of program instructions. It is contemplated that those skilled in the art having reference to this specification will be readily able to construct such a software approach, for those implementations in which the processing resources are capable of timely performing such decoding.

Referring back to the functional flow of FIG. 2, filtering and conversion function 21 in receiver 20 processes the signal that is received over transmission channel C. Function 21 applies the appropriate analog filtering, analog-to-digital conversion, and digital filtering to the received signals, again depending upon the technology of the communications. This filtering can also include the application of a time domain equalizer (TEQ) to effectively shorten the length of the impulse response of the transmission channel C, in those applications for which such equalizing is appropriate. Serial-to-parallel converter 23 converts the filtered datastream into a number of samples that are applied to demodulator 24, which recovers the modulating symbols by reversing the modulation performed by modulator 14 in transmitter 10. For example, in the DMT case, demodulator 24 would include a DFT function, followed by a frequency-domain equalizer to divide out the frequency-domain response of the effective channel, thus recovering an estimate of the modulating symbols. Symbol-to-bit decoder function 26 then demaps the recovered symbols, and applies the resulting bits to LDPC decoder function 28.

LDPC decoder function 28 reverses the encoding that was applied in the transmission of the signal, to recover an output bitstream that corresponds to the input bitstream upon which the transmission was based. This output bitstream is then forwarded to the host workstation or other recipient.

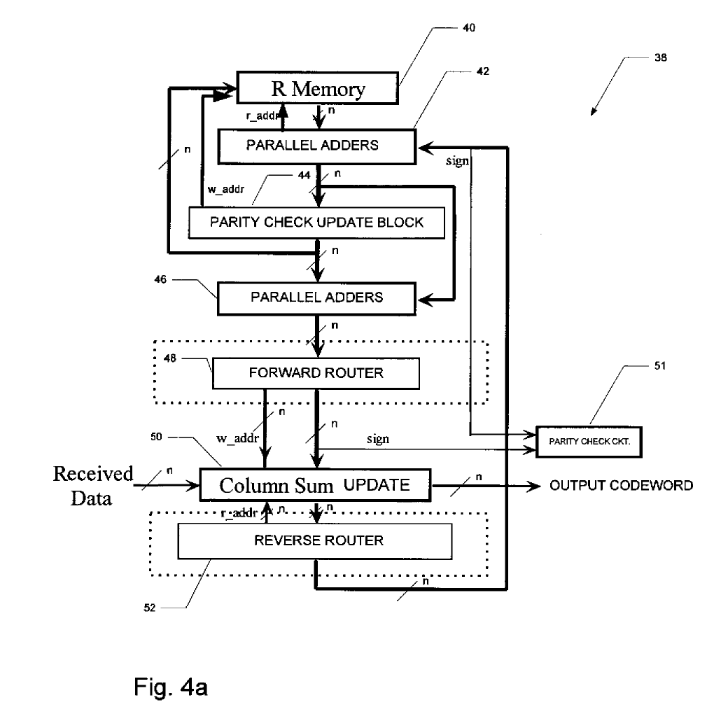

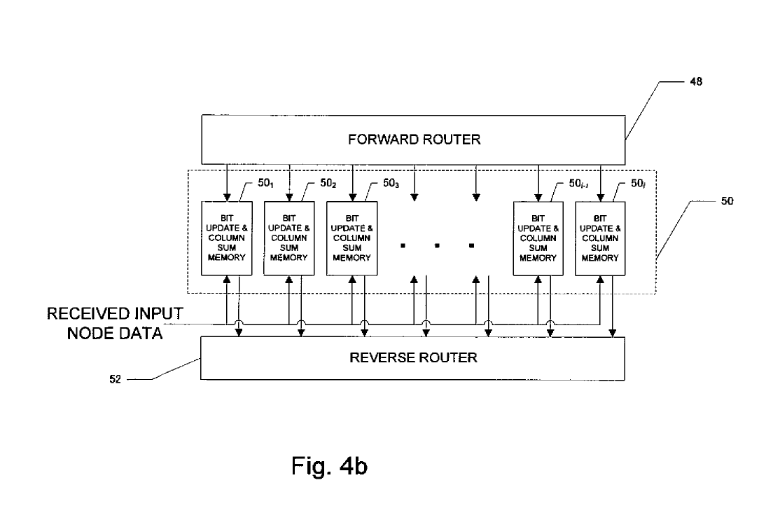

FIG. 4a functionally illustrates the construction of LDPC decoder circuitry 38 in transceiver 25, which performs LDPC decoder function 28 in the data flow diagram of FIG. 3, according to an embodiment of the invention. It is contemplated that the functions illustrated in FIG. 4a may in large part be realized by custom logic circuitry for performing the stated functions; alternatively, some of these functions may be carried out by way of programmable logic circuitry executing instructions stored in and accessed from program memory. It is contemplated that those skilled in the art having reference to this specification will be readily able to implement the logic circuitry and functionality of LDPC decoder circuitry 38 in a suitable fashion for particular applications, without undue experimentation.

The arrangement of FIG. 4a according to this embodiment of the invention generally follows the functional flow of LDPC decoding as described, for example, in the above-incorporated U.S. Patent Application Publication No. US 2007/0086539 A1 and as shown in FIG. 1a. LDPC decoder function 28, as executed by LDPC decoder circuitry 38 in this embodiment of the invention, solves the encoding equation:

H·c=0

over Galois field GF(2), in which vector c represents the encoded codeword vector (the source message cᵢ combined with the corresponding parity check bits cₚ), and in which H represents the parity check matrix, which is known. The solution of this matrix equation is performed, in this embodiment of the invention and as described in the above-incorporated U.S. Patent Application Publication No. US 2007/0086539 A1, as the iterative two-step belief propagation (or reverse-propagation) process of:
1. Estimating a value Rₘⱼ for each of j input nodes in each of m rows of the checksum (H·c), using the current probability values from the other input nodes, and setting the result of the checksum for row m to 0; and
2. Updating a sum L(qⱼ) for each of the j input nodes from a combination of Rₘⱼ values in the same column.
   The iterations continue until a termination criterion is reached. A preferred termination criteria is the earlier of (i) evaluation of the matrix operation H·c=0 (mod 2), using “hard” decisions from the LLRs L(qⱼ) as the codeword vector c, and (ii) completion of a specified number of iterations.

LDPC decoder circuitry 38 of FIG. 4a includes random access memory (RAM) 40 for storing the Rₘⱼ estimates from step (1) of the two-step process outlined above, within each iteration of the belief propagation. As described above, each Rₘⱼ value stored in RAM 40 corresponds to a log-likelihood-ratio (LLR) estimate of the data state of an input node j that is summed in row m of the parity check matrix, with that estimate based on the LLR values of the other input nodes that also participate in row m, but not using the value of input node j itself. In each decoder cycle, R¹ₘⱼ values are read from RAM 40 and applied (via parallel adders 42) to parity check update block 44, for use in decoder iteration i for that row m. This read operation is performed by RAM 40 in connection with a memory address, communicated on address lines r_addr, indicating the row m and columns j to which these Rⁱₘⱼ values correspond; alternatively, this read address may be generated internally to RAM 40, or by another circuit function. Also in each decoder cycle, new contents are written to RAM 40 and include the most recent Rⁱ⁺¹_{m′j} estimate generated by parity check update block 44 in a decoder iteration i for a row m′ (typically differing from the row or rows for which the Rⁱₘⱼ values are read in this decoder cycle) and will be the Rₘⱼ values to be used in the next decoding iteration i+1 for that row m′. These new contents are presented in combination with a memory address corresponding to row m′ and columns j, on lines w_addr.

In FIG. 4a, the various data lines, for example the data lines output by RAM 40 to parallel adders 42, are shown as n bits wide. In this regard, it is to be understood that this indication is intended to show that these data lines can communicate one or more bits in parallel, and it is also to be understood that the various data lines within LDPC decoder circuitry 38 may be of different bit widths from one another.

According to this embodiment of the invention, as will be described below, RAM 40 is constructed as a single-port random access memory, to permit both a write operation (of Rⁱ⁺¹_{m′j} estimates) and a read operation (of Rⁱₘⱼ values) within a single decoder cycle. This single-port implementation of RAM 40 includes logic for performing both memory accesses within that single decoder cycle, without requiring RAM 40 to be implemented as a two-port memory.

Similarly as described above relative to FIG. 1a, RAM 40 has one or more outputs coupled to a corresponding negative (subtracting) input of parallel adders 42. Parallel adders 42 are constructed as conventional adders, arranged in parallel, and each one which performs a subtraction:

L(qₘⱼ)=L(qⱼ)−Rₘⱼ

for a corresponding column j of current row m of the parity check sum. The minuend L(qⱼ) for a given column j is provided by reverse router 52, and is the most recent LLR estimate of the data state of the input bit associated with column j. The subtraction performed by parallel adders 42 thus effectively updates an estimate L(qₘⱼ) of the probability of the input node value for column j, but excluding the contribution to that estimate generated by evaluation of the check sum of row m. This permits the updating of the estimate Rₘⱼ as the data state of input node j indicated by the LLR values of the other input nodes that also participate in row m. These updated “extrinsic” value estimates L(qₘⱼ) are then applied by parallel adders 42 to parity check update function 44, which produces updated estimates Rⁱ⁺¹ₘⱼ for use in the next, i+1, iteration.

As in the circuitry of FIG. 1a, the construction and operation of parity check update function 44, according to this embodiment of the invention, can follow the approach described in the above-incorporated U.S. Pat. No. 7,178,080 B2. Each incoming extrinsic value estimate L(qₘⱼ) provided by parallel adders 42 serves as an index into a look-up table within parity check update function 44. This look-up table outputs the value Ψ(L(qₘⱼ)) of an Ψ function for a corresponding row m of the parity check matrix for that column j, and accumulator circuitry within parity check update function 44 produces a sum Σ[Ψ(L(qₘⱼ))] of the retrieved values over all of the columns participating in that row m. For each column j contributing to a check sum row m, this sum Σ[Ψ(L(qₘⱼ))] is applied to an adder within parity check update function 44 to subtract the look-up table output Ψ(L(qₘⱼ)) for that row m and an associated column j, which is the column's own contribution to that sum. The result of this subtraction is a set of amplitude values Aₘⱼ, each associated with one of the columns j participating (i.e., its corresponding element of parity check matrix H is not zero-valued) in this row m. Parity check update function 42 applies the Ψ function is applied to these amplitude values Aₘⱼ, again via a look-up table. For each participating column j, parity check update function 42 applies a sign (+/−) to the LUT output based on a logical odd/even determination of the number of negative LLR probabilities, excluding each column's own contribution. The result of these operations is an updated estimate value Rⁱ⁺¹ₘⱼ for the LLR of input node j, for each row m and as based on the LLRs of the other input nodes participating in that row m (with no contribution from column j itself to the check sum of row m). These updated estimate values Rⁱ⁺¹ₘⱼ are written to RAM 40, as shown in FIG. 4a and as described above.

As described in U.S. Patent Application Publication No. US 2007/0086539 A1, parity check update function 44 can be constructed to simultaneously operate on multiple rows of the parity check matrix, depending on the particular application and available resources.

Variations to this construction and operation of parity check update function 44, may alternatively be used, in connection with this embodiment of the invention, according to the available circuitry and performance of the specific implementation.

The estimate values Rⁱ⁺¹ₘⱼ are also output by parity check update function 44 to parallel adders 46, which include multiple arithmetic adder circuits connected in parallel, for example as described in the above-incorporated U.S. Pat. No. 7,178,080 B2. Parallel adders 46 each receive, at another input, a corresponding output from one of parallel adders 44 corresponding to a per-row LLR probability estimate value L(qₘⱼ) used by parity check update function 44. Parallel adders 46 calculate the updated log likelihood ratio (LLR) estimates L(qⱼ) for each input node, according to:

L(qⱼ)=L(qₘⱼ)+Rₘⱼ

Essentially, the addition performed by parallel adders 46 reverses the subtraction performed by parallel adders 42. Parallel adders 46 add, for a given input node j, the updated estimate Rⁱ⁺¹ₘⱼ, which is based on the LLR values of the other input nodes participating in the sum of parity check matrix row m but not using the value of input node j itself, plus the current value of estimate L(qₘⱼ) generated by parallel adders 42, which as described above is an estimate of the input node value for column j excluding the contribution to that estimate generated by evaluation of the check sum of row m. These updated values L(qⱼ) are then forwarded to forward router circuitry 48.

Router circuitry 48 is constructed as a bank of multiplexers and demultiplexers that forwards the appropriate estimate values L(qⱼ) to a corresponding one of column sum update circuits 50. The information forwarded by forward router circuitry 48 includes each of the estimate values L(qⱼ) (numbering, for example, the number of columns j participating in a row m of the parity check matrix), along with a write address value w_addr indicating the column j to which the estimate L(qⱼ) pertains. If desired, the sign bit of each estimate value L(qⱼ) from parallel adders 46 can be forwarded to parity check circuit 51. In this case, parity check circuit 51 also receives the sign bit of each estimate value L^{h}(qⱼ) for each input node from the previous subset, from the values applied to parallel adders 42 as shown in FIG. 4a. Parity check circuit 51 can compare these respective sign bits of the LLR estimates for an input node to determine whether the sign bit has changed state for its column j. This detection of a difference in sign from one iteration to the next is useful in determining whether the decoding has converged to a valid result.

FIG. 4b illustrates the arrangement of router circuitry 48 and column sum update circuits 50 in further detail. As shown in FIG. 4b, column sum update circuits 50 are arranged as a plurality of instances of bit update and column sum memory 50₁ through 50ᵢ, each having an input coupled to router circuitry 48, and also having an input for receiving input node data in this example. An output of each instance of bit update and column sum memory 50₁, through 50ᵢ is coupled to reverse router circuitry 52, which effectively reverses the routing of router circuitry 38. As such, previously stored estimate values L(qⱼ) in column sum update circuits 50 are obtained by reverse router circuitry 52, in response to a read address value indicating the column j of the desired data presented by reverse router circuitry 52 on lines r_addr (FIG. 4a).

Reverse router circuitry 52 is also constructed as a bank of multiplexers and demultiplexers, and forwards the retrieved estimate values L(qⱼ) from corresponding ones of column sum update circuits 50 to parallel adders 42, for use in the next decoding iteration, as described above. These retrieved estimate values L(qⱼ) output by column sum update circuits 50 can also serve as all or part of the output codeword, and forwarded by other circuitry upon a determination (e.g., by parity check circuit 51) that the decoding operation has sufficiently converged.

Alternatively, parity check function 51 can be constructed as logic that performs a slicing function on the output LLR estimates from column sum update circuits 50, converts these values to “hard” decisions, and then determines whether the parity check equation is satisfied by the current estimates.

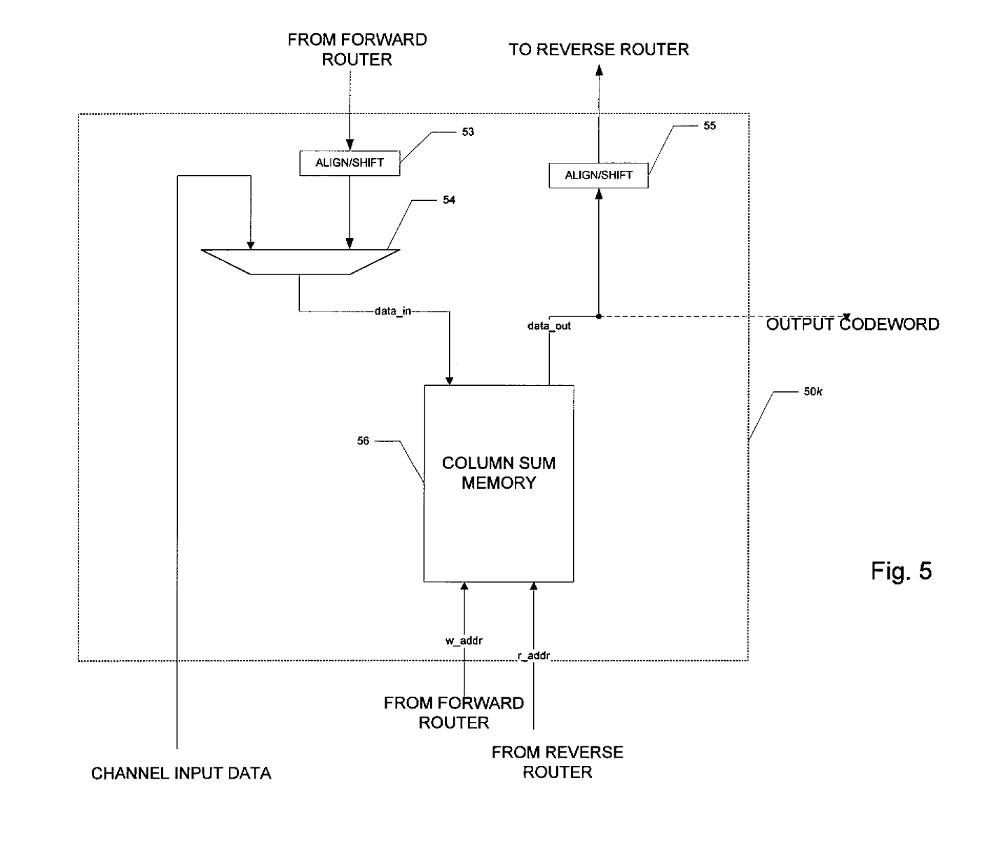

The construction of one of column sum update circuits 50 according to an embodiment of the invention will now be described relative to FIG. 5, with reference to an example of column sum update circuit 50k shown in that Figure. Of course, column sum update circuits 50 can be constructed according to other architectures and arrangements, as useful in LDPC decoding or such other belief propagation decoding being implemented. In any event, however, according to this embodiment of the invention, column sum update circuits 50 include single-port RAM to which both read and write operations can be performed within a decoder cycle, as will become apparent from the following description.

The example of column sum update circuit 50k illustrated in FIG. 5 essentially follows that described in the above-incorporated U.S. Pat. No. 7,139,959 B2. According to that example, column sum update circuit 50k is effectively an accumulator that maintains, from iteration to iteration, current values of the LLRs of the summed column terms L(qⱼ). This accumulator function of column sum update circuit 50k is served by column sum memory 56, which in this embodiment of the invention is a single-port random access memory, the construction of which will be described in further detail below. In this example, multiplexer 54 controls whether the summed column terms L(qⱼ) from forward router circuitry 58 are to be stored in column sum memory 56, or if instead, for the initial estimate iterations, the received channel input data are to be stored in column sum memory 56 as the starting point for each input node j. The addresses to which the summed column terms L(qⱼ) are to be stored, in write operations applied to column sum memory 56, are communicated to column sum memory 56 by forward router circuitry 48, on address lines w_addr as shown. Alternatively column sum update circuit 50 can have its own address sequence function that advances and maintains the memory address for each iteration.

Column sum memory 56 presents its output to reverse router circuitry 52 (FIG. 4a), in response to read accesses from locations in column sum memory 56 indicated by address values communicated by reverse router circuitry 52 on address lines r_addr as shown in FIG. 5. As shown in FIG. 4a and as discussed above, this output of column sum memory 56 also presents part of the output codeword, which is forwarded by other circuitry outside of column update circuit 50k upon a determination that the decoding operation has sufficiently converged.

As described in the above-incorporated U.S. Pat. No. 7,139,959 B2, align/shift block 53 at the input (and also align/shift block 55 at the output) are provided to align the incoming and outgoing data values in the event that LDPC decoder circuitry 38 operates according to a parallelization factor of greater than one.

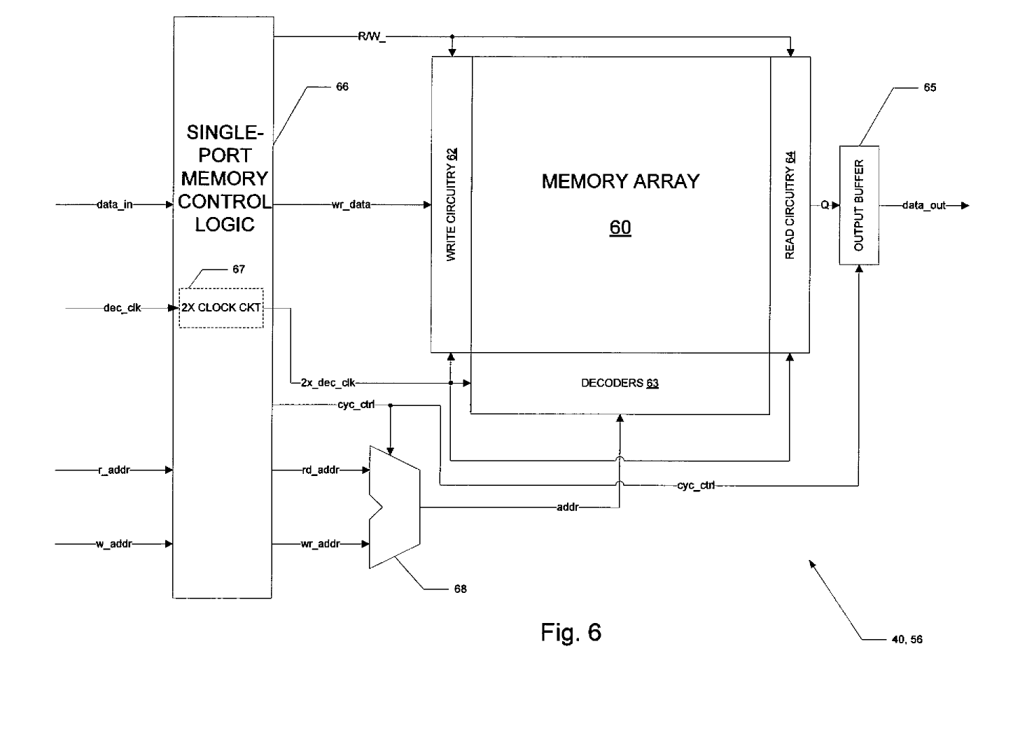

The construction of single-port column sum memory 56, according to an embodiment of this invention, is shown in FIG. 6. This construction can also be used in connection with single-port RAM 40, which stores the Rₘⱼ estimates as described above in connection with FIG. 4a.

Memory array 60 includes the desired number of memory cells, typically arranged in rows and columns as conventional for RAM architectures. It is contemplated that, when implemented in LDPC decoder circuitry 38 as in this embodiment of the invention, these memory cells will be of the static RAM type, each memory cell consisting of cross-coupled inverters with metal oxide semiconductor (MOS) pass gates for coupling the cell nodes to differential bit lines of its array column, in response to activation of a word line selecting the row of that memory cell. Decoders 63 are shown in block form in FIG. 6, and are constructed in the conventional manner for row and column decoders, as appropriate for the desired organization and architecture of memory array 60.

Write circuitry 62 is coupled to memory array 60, and includes write drivers and the like for writing input data (received on line data_in) to one or more memory cells in memory array 60 selected by decoders 63 in response to an address value on lines addr. This write operation is enabled by an active low level on control line R/W_, and synchronously with clock signal 2x_dec_clk. Conversely, read circuitry 64 is coupled to memory array 60, and includes sense amplifiers and corresponding circuitry for sensing the data state of one or more memory cells in memory array 60 selected by decoders, in response to the address on lines addr. This read operation is enabled by an active high level on control line R/W_ in this example, and synchronously with clock signal 2x_dec_clk. The sensed output data states are forwarded on line Q by read circuitry 64 to output buffer 65, which in turn presents the output data on lines data_out, as controlled by a control signal on line cyc_ctrl.

Column sum memory 56 (and RAM 40, if applicable) also includes control logic 66 for controlling its operation according to this embodiment of the invention. As mentioned above, each of column sum memory 56 and RAM 40 are read once per decoder cycle, and are written with updated contents once per decoder cycle. It has been discovered, according to this invention, that the performance of iterative complex decoding operations is limited by the execution of the logic operations, rather than by memory performance. For the example of LDPC decoding described above, the duration of the decoder cycle is determined by the time required to execute the parity check sum updates by parallel adders 42, 46 and parity check update block 44, in combination with the routing operations of router circuitry 48, 52. Indeed, it has been observed, in connection with this invention, that the memory cycle time for both write and read operations to SRAM memory is less than one-half the duration of the decoder cycle time. For example, a typical LDPC decoder cycle time may be on the order of 10 nsec, while the read and write cycle times for the SRAM memory resources may be as short as 3 nsec. As a result, even if memory performance is improved, that improvement would have no effect on the performance of the decoder as a whole.

This embodiment of the invention takes advantage of this relationship between memory access and cycle times and decoder cycle times, by implementing one or both of column sum memories 56, and RAM 40 as single-port RAM that is controlled to ensure the cooperation of one write operation and one read operation within each decoder cycle. Referring to FIG. 6, this control is provided by control logic 66, the function of which will be described below. It is contemplated that control logic 66 can be readily realized by those skilled in the art having reference to this specification and to the description of the operation and functionality of control logic 66, by way of combinational logic, sequential logic, programmable logic, or some combination.

As shown in FIG. 6, control logic 66 includes 2X clock circuit 67. In this example, 2X clock circuit 67 receives decoder clock signal dec_clk at an input, and from that clock generates a doubled frequency clock signal applied to the peripheral circuits (write circuit 62, decoders 63, read circuitry 64) in memory 40, 56. Decoder clock signal dec_clk corresponds to a clock signal that is applied to the various functions in LDPC decoder circuit 38, and at a frequency corresponding to the operation of those decoder functions, while clock signal 2X_dec_clk is generated by 2X clock circuit 67 at twice that frequency. As such, 2X clock circuit 67 may be constructed as a conventional clock-doubling circuit, as known in the art. Alternatively, if a master clock signal (or clock signal generated from such a master clock signal) within LDPC decoder circuit 38 operating at twice the decoder frequency is available, that master clock signal can be used to clock the peripheral circuits of memory 40, 56, and then applied to 2X clock circuit 67, in the form of a 2X frequency divider, to produce the decoder clock signal dec_clk at half that frequency.

If the necessary memory cycle times are sufficiently short, relative to the decoder cycle time, more than one read and one write operation may be performed within each decoder cycle. For example, if the memory cycle time is one-fourth of the decoder cycle time, or shorter, two reads and two writes may be performed to single-port RAM in each decoder cycle. These additional operations may enable a single RAM array to cover multiple instances of column sum update circuits 50, for example.

Control logic 66 receives input data on lines data_in and, during write cycles, forwards that input data to write circuitry 62 on lines wr_data. In both write and read operations, control logic 66 receives address and data information from the corresponding decoder functions (FIG. 4a) with which memory 40, 56 is cooperating. As shown in FIG. 6, control logic 66 receives the memory address to which data are to be written in memory 40, 56 on lines w_addr, and the memory address from which data are to be read from memory 40, 56, on lines r_addr. These address lines w_addr, r_addr presented to control logic 66 correspond, in this example, to the similarly named address lines shown in FIG. 4a; alternatively, memory address sequencer circuitry may be included within control logic 66 itself, in those embodiments in which the memory resource is generating and keeping track of the rows and columns of the parity check operation currently being evaluated. Control logic 66 presents the read memory address to an input of multiplexer 68 on lines rd_addr, and presents the write memory address to another input of multiplexer 68 on lines wr_addr. The output of multiplexer 68 is presented to decoders 63 of memory 40, 56 on lines addr, and constitutes one or the other of read memory address rd_addr and write memory address wr_addr, as selected by multiplexer 68 in response to the state of control signal cyc_ctrl applied to its select input.

According to this embodiment of the invention, control logic 66 generates control signal cyc_ctrl and read/write signal R/W_ to cause both a read cycle and a write cycle, from the standpoint of memory array 60, within each decoder cycle. As shown in FIG. 6, read/write signal R/W_ is generated by control logic 66 and applied to write circuitry 62 and read circuitry 64, and control signal cyc_ctrl is generated by control logic 66 and applied to output buffer 65 and the select input of multiplexer 68. The state of these signals cyc_ctrl, R/W_ indicate whether a read cycle or a write cycle is being performed. In a write cycle, control signal cyc_ctrl causes multiplexer to select write memory address wr_addr for application to decoders 63 via address lines addr, and read/write signal R/W enables write circuitry 62 to apply the value on data lines wr_data to the memory cells selected by decoders 63 according to the address value on lines addr. Conversely, in a read cycle, control signal cyc_ctrl (at an opposite data state from that which enables a write) causes multiplexer 68 to couple the read memory address on lines rd_addr to address lines addr, read/write signal R/W disables write circuitry 62 and enables read circuitry 64. In this read operation, control signal cyc_ctrl causes output buffer 65 to receive the data value from the cells of memory array 60 that were selected by decoders 63 according to the address value on lines addr, and to forward that data value on one or more output lines data_out.

As mentioned above, according to this embodiment of the invention, because memory 40, 56 can operate at a cycle time that is one-half the decoder cycle duration, and because the decoder cycle duration is defined by the minimum time required to carry out decoder operations, memory 40, 56 is controlled to perform one memory read and one memory write in each decoder cycle. As opposed to memory architectures of the “double-data-rate” (DDR) type, memory 40, 56 is not reading or writing at twice the data rate; rather, the decoding functions are limited in the data that can be provided or received. Instead, because of the nature of the decoding task, particularly in this LDPC decoding case, the operation of memory 40, 56 at half-cycle time (relative to the decoder cycle) to perform one read and one write operation fully satisfies the data demands of those decoder functions. In addition, this half-cycle operation enables memories 40, 56 to be realized as single-port, rather than two-port, memory, which greatly reduces the chip area and thus the manufacturing cost of the memory resources and thus the LDPC decoder circuit 38 in general.

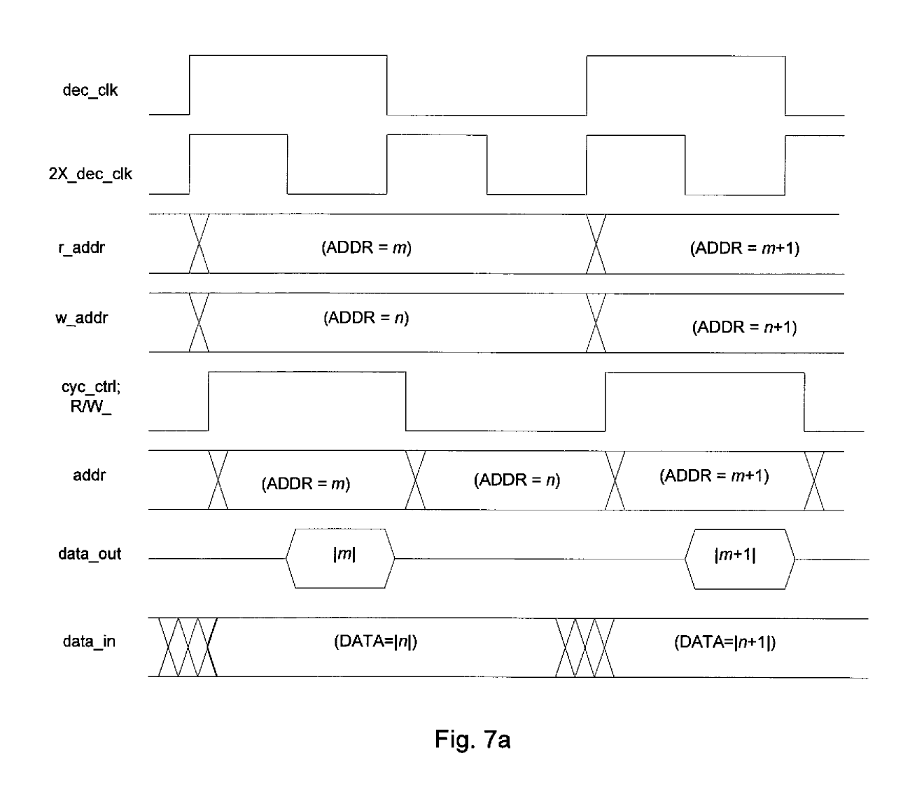

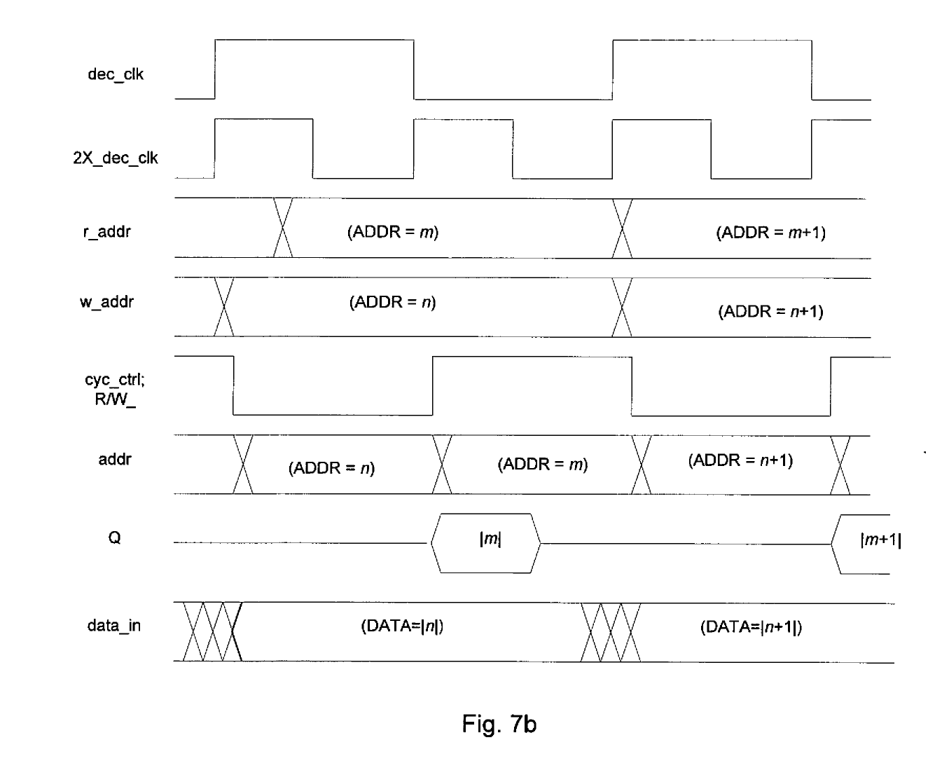

FIG. 7a illustrates the generalized timing of the read and write memory accesses within a decoder cycle, according to one example of the operation of memory 40, 56. As shown in FIG. 7a, decoder clock signal dec_clk is at twice the frequency of clock signal 2X_dec_clk generated by 2X clock circuit 67 from the decoder clock, or vice versa if 2X clock circuit 67 is realized instead as a frequency divider. According to this example, one read address value (e.g., address m) and one write address value (e.g., address n) are presented to control logic 66 on lines r_addr, w_addr, respectively, in each cycle of decoder clock dec_clk. The specific timing of valid read and write address values on lines r_addr, w_addr within a decoder cycle can vary relative to one another, and can be positioned at various points within the decoder cycle, depending on the construction and operation of LDPC decoder circuit 38.

According to this example, control logic 66 operates to perform a read operation in the first half-cycle of each cycle of decoder clock dec_clk (i.e., the first cycle of clock signal 2X_dec_clk), and a write operation in the second half-cycle. This operation is indicated, in the example of FIG. 7a, by control logic 66 issuing control signal cyc_ctrl and read/write signal R/W_ at a high logic level for read operations, and at a low logic level for write operations. While both of control signal cyc_ctrl and read/write signal R/W_ are at the same logic levels in this example, for convenience, this correspondence between these signals is, of course, not necessary in practice; conversely, if signals cyc_ctrl and R/W_ operate at the same logic levels and the same timing, a single signal may be used as both. In the example of FIG. 7a, during the first half-cycle of decoder clock dec_clk, in which control signal cyc_ctrl is at a high logic level, lines addr at the output of multiplexer 68 present the read memory address on lines r_addr, namely the value m in this example, to decoders 63. In response to that address level, and to the high logic level of read/write signal R/W_ and control signal cyc_ctrl in this read operation, the contents of memory location m are presented by read circuitry 64 and output buffer 65 on lines data_out, toward the end of the first half-cycle of decoder clock dec_clk.

In the second half-cycle of decoder clock dec_clk, in this example, control logic 66 issues a low logic level at control signal cyc_ctrl and read/write signal R/W_to enable write circuitry 62 to perform a write operation to memory array 60, at the memory location indicated by write memory address w_addr n. Multiplexer 68 selects write memory address lines wr_addr, in response to this low level of control signal cyc_ctrl, and presents the address value n is presented to decoders 63. Write circuitry 62 is enabled by the low logic level of read/write signal R/W_ to write the intended data value (presented on lines data_in to control logic 66) to the memory address n indicated on lines w_addr (and address lines addr in this second half-cycle). In addition, the low logic level of control signal cyc_ctrl, in this embodiment of the invention, places output buffer 65 into a high-impedance state.

According to this invention, the order in which read and write operations are performed within each decoder cycle is not important. Rather, the designer may select one order or the other when implementing this embodiment of the invention. For example, the specific arrangement and operation of the decoder functions within LDPC decoder circuit 38 may result in one of the read and write addresses becoming available before the other. In such a case, it may be preferable to perform the operation corresponding to the earlier-arriving address in the first half-cycle of the decoder clock.

FIG. 7b illustrates this situation. In this example, the write memory address is received by control logic 66 on lines w_addr earlier in the decoder cycle than is the read memory address on lines r_addr. In this case, control logic 66 is configured to issue the low level of control signal cyc_ctrl and read/write signal R/W_in the first half-cycle of decoder clock dec_clk, responsive to which a write operation is performed by write circuitry 62, at the cells of memory array 60 corresponding to memory address n and selected by decoders 63 in response to the value forwarded by multiplexer 68. Conversely, in the second half-cycle of decoder clock dec_clk, control signal cyc_ctrl and read/write signal R/W_ are driven to a high logic level by control logic 66, to read the contents of memory location m indicated by the read memory address on lines r_addr, and forwarded to decoders 63 by multiplexer 68 by that high logic level on control signal cyc_ctrl.

In either case, LDPC decoder circuit 38 according to this embodiment of the invention can construct either or both of its memory resources (e.g., RAM 40 and column sum memories 56) as single-port RAM, while still permitting a read from that memory resource and a write to that memory resource within each decoder cycle. The chip area and overhead circuitry required to implement these decoder memory resources is thus greatly reduced from conventional decoders, especially considering that relatively small memories (such as those involved in LDPC and other decoding) are especially inefficient to realize, from the standpoint of cells per unit chip area.

As noted above, this embodiment of the invention is described in connection with an embodiment that is directed to LDPC decoder circuitry. It is contemplated that this invention is especially beneficial when implemented in such an application, considering the relative complexity of the parity check sum update and column sum update operations; this complexity defines the decoder cycle time, and thus the period within which both the read and write accesses to memory are to occur. In addition, LDPC decoding is well-suited to benefit from this invention, considering that the decoding operation requires a read from memory and an update to that memory within each decoder cycle. However, it is contemplated that other decoder circuits, including those operating according to algorithms and codes other than LDPC, can also similarly benefit from this invention. As such, it is contemplated that this invention will be useful in such other applications.

While the present invention has been described according to its preferred embodiments, it is of course contemplated that modifications of, and alternatives to, these embodiments, such modifications and alternatives obtaining the advantages and benefits of this invention, will be apparent to those of ordinary skill in the art having reference to this specification and its drawings. It is contemplated that such modifications and alternatives are within the scope of this invention as subsequently claimed herein.

What is claimed is:

1. Decoder circuitry arranged for decoding a received data stream, comprising:
a first memory for storing a first set of decoder values;
first decoder logic circuitry, coupled to receive selected contents of the first memory, for updating one or more of the first set of decoder values responsive to a second set of decoder values, and having an output coupled to present the updated one or more of the first set of decoder values to the first memory for storage;
a second single-port memory for storing the second set of decoder values; and
second decoder logic circuitry, coupled to receive results from the first decoder logic circuitry, the second update circuitry for updating one or more of the second set of decoder values responsive to the results from the first decoder logic circuitry, and having an output coupled to present the updated one or more of the second set of decoder values to the second single-port memory for storage;
wherein the second single-port memory is coupled to present one or more of the second set of decoder values to the first decoder logic circuitry;
and wherein the second single-port memory comprises:
an array of memory cells arranged in rows and columns;
peripheral circuitry coupled to the array of memory cells, for writing data to and reading data from a selected memory cell in the array, responsive to a read/write control signal indicating whether a read or write is to be performed; and
logic circuitry for generating and applying to the peripheral circuitry, within a single operating cycle of the first and second decoder logic circuitry, the read/write control signal indicating a read operation in combination with a read memory address during a read portion of the operating cycle, and the read/write control signal indicating a write operation in combination with a write memory address during a write portion of the operating cycle.

2. The decoder circuitry of claim 1, wherein the first memory is a single-port memory, and comprises:
an array of memory cells arranged in rows and columns;
peripheral circuitry coupled to the array of memory cells, for writing data to and reading data from a selected memory cell in the array, responsive to a read/write control signal indicating whether a read or write is to be performed; and
logic circuitry for generating and applying to the peripheral circuitry, within a single operating cycle of the first and second decoder logic circuitry, the read/write control signal indicating a read operation in combination with a read memory address during a read portion of the operating cycle, and the read/write control signal indicating a write operation in combination with a write memory address during a write portion of the operating cycle.

3. The decoder circuitry of claim 1, wherein the first decoder logic circuitry comprises:
a first plurality of adders in parallel with one another, each adder receiving a corresponding one of the first set of decoder values, and receiving a corresponding one of the second set of decoder values, each adder for subtracting the one of the first set of decoder values from the one of the second set of decoder values;
parity check update logic, for generating updated ones of the first set of decoder values responsive to the results of the subtractions by the first plurality of adders; and
a second plurality of adders in parallel with one another, each adder receiving a corresponding one of the updated estimate values, and receiving a corresponding one of the results of the subtractions by the first plurality of adders, each adder for adding the one of the updated estimate values and the one of the results of the subtractions.

4. The decoder circuitry of claim 3, wherein the first memory is a single-port memory, and comprises:
an array of memory cells arranged in rows and columns;
peripheral circuitry coupled to the array of memory cells, for writing data to and reading data from a selected memory cell in the array, responsive to a read/write control signal indicating whether a read or write is to be performed; and
logic circuitry for generating and applying to the peripheral circuitry, within a single operating cycle of the first and second decoder logic circuitry, the read/write control signal indicating a read operation in combination with a read memory address during a read portion of the operating cycle, and the read/write control signal indicating a write operation in combination with a write memory address during a write portion of the operating cycle, wherein the logic circuitry receives input data corresponding to the updated ones of the first set of decoder values from the parity check update logic.

5. The decoder circuitry of claim 1, wherein the second single-port memory is arranged as a plurality of instances of the second single-port memory;
and wherein the second decoder logic circuitry comprises:
a plurality of column sum update circuits, each column sum update circuit comprising:
an instance of the second single-port memory; and
an input multiplexer, for selectively applying one of received input data and results from the first decoder logic circuitry to an input of the instance of the second single-port memory.

6. The decoder circuitry of claim 5, wherein the second decoder logic circuitry comprises:
forward router circuitry, for routing each of a plurality of results from the first decoder logic circuitry to one of the plurality of column sum update circuits; and
reverse router circuitry, for routing an updated one of the second set of decoder values from one of the plurality of column sum update circuits to a corresponding input of the first decoder logic circuitry.

7. The decoder circuitry of claim 5, wherein each instance of the second single-port memory presents output data read operation in combination with the read memory address during the read portion of the operating cycle;
and wherein at least a portion of the output data corresponds to an output codeword from the decoder circuitry.

8. The decoder circuitry of claim 1, wherein the first decoder logic circuitry evaluates a parity check sum corresponding to a Low Density Parity Check (LDPC) code.

9. The decoder circuitry of claim 1, wherein the logic circuitry of the second single-port memory generates the read/write control signal indicating a read operation before generating the read/write control signal indicating a write operation, within the operating cycle.

10. The decoder circuitry of claim 1, wherein the logic circuitry of the second single-port memory generates the read/write control signal indicating a write operation before generating the read/write control signal indicating a read operation, within the operating cycle.

11. An integrated circuit including a receiver function for receiving and decoding encoded digital data, comprising:
a first interface, for receiving communicated signals from a communications facility and presenting, at an output, a digital data stream corresponding to the received signals;
signal processing logic, coupled to the first network interface, for receiving and processing the digital data stream;
a second interface, for communicating processed data corresponding to the digital data stream; and
decoder circuitry, for decoding at least a portion of the digital data stream that is encoded according to an error detection and correction code, the decoder circuitry comprising:
a first memory for storing a first set of decoder values;
first decoder logic circuitry, coupled to receive selected contents of the first memory, for updating one or more of the first set of decoder values responsive to a second set of decoder values, and having an output coupled to present the updated one or more of the first set of decoder values to the first memory for storage;
a second single-port memory for storing the second set of decoder values; and
second decoder logic circuitry, coupled to receive results from the first decoder logic circuitry and to receive input data corresponding to an encoded portion of the digital data stream, the second update circuitry for updating one or more of the second set of decoder values responsive to the results from the first decoder logic circuitry, and having an output coupled to present the updated one or more of the second set of decoder values to the second single-port memory for storage;
wherein the second single-port memory is coupled to present one or more of the second set of decoder values to the first decoder logic circuitry;
and wherein the second single-port memory comprises:
an array of memory cells arranged in rows and columns;
peripheral circuitry coupled to the array of memory cells, for writing data to and reading data from a selected memory cell in the array, responsive to a read/write control signal indicating whether a read or write is to be performed; and
logic circuitry for generating and applying to the peripheral circuitry, within a single operating cycle of the first and second decoder logic circuitry, the read/write control signal indicating a read operation in combination with a read memory address during a read portion of the operating cycle, and the read/write control signal indicating a write operation in combination with a write memory address during a write portion of the operating cycle.

12. The integrated circuit of claim 11, wherein the first memory is a single-port memory, and comprises:
an array of memory cells arranged in rows and columns;
peripheral circuitry coupled to the array of memory cells, for writing data to and reading data from a selected memory cell in the array, responsive to a read/write control signal indicating whether a read or write is to be performed; and
logic circuitry for generating and applying to the peripheral circuitry, within a single operating cycle of the first and second decoder logic circuitry, the read/write control signal indicating a read operation in combination with a read memory address during a read portion of the operating cycle, and the read/write control signal indicating a write operation in combination with a write memory address during a write portion of the operating cycle.

13. The integrated circuit of claim 12, wherein the first decoder logic circuitry comprises:
a first plurality of adders in parallel with one another, each adder receiving a corresponding one of the first set of decoder values, and receiving a corresponding one of the second set of decoder values, each adder for subtracting the one of the first set of decoder values from the one of the second set of decoder values;
parity check update logic, for generating updated ones of the first set of decoder values responsive to the results of the subtractions by the first plurality of adders; and
a second plurality of adders in parallel with one another, each adder receiving a corresponding one of the updated estimate values, and receiving a corresponding one of the results of the subtractions by the first plurality of adders, each adder for adding the one of the updated estimate values and the one of the results of the subtractions.

14. The integrated circuit of claim 11, wherein the second single-port memory is arranged as a plurality of instances of the second single-port memory;
and wherein the second decoder logic circuitry comprises:
a plurality of column sum update circuits, each column sum update circuit comprising:
an instance of the second single-port memory; and
an input multiplexer, for selectively applying one of received input data and results from the first decoder logic circuitry to an input of the instance of the second single-port memory;
forward router circuitry, for routing each of a plurality of results from the first decoder logic circuitry to one of the plurality of column sum update circuits; and
reverse router circuitry, for routing an updated one of the second set of decoder values from one of the plurality of column sum update circuits to a corresponding input of the first decoder logic circuitry.

15. The integrated circuit of claim 14, wherein each instance of the second single-port memory presents output data read operation in combination with the read memory address during the read portion of the operating cycle;
and wherein at least a portion of the output data corresponds to an output codeword from the decoder circuitry.

16. The integrated circuit of claim 11, wherein the first decoder logic circuitry evaluates a parity check sum corresponding to a Low Density Parity Check (LDPC) code.

17. The integrated circuit of claim 11, wherein the logic circuitry of the second single-port memory generates the read/write control signal indicating a read operation before generating the read/write control signal indicating a write operation, within the operating cycle.

18. The integrated circuit of claim 11, wherein the logic circuitry of the second single-port memory generates the read/write control signal indicating a write operation before generating the read/write control signal indicating a read operation, within the operating cycle.

19. Decoder circuitry arranged for decoding a received data stream, comprising:
a first memory for storing a first set of decoder values;
first decoder logic circuitry, coupled to receive selected contents of the first memory, for updating one or more of the first set of decoder values responsive to a second set of decoder values, and having an output coupled to present the updated one or more of the first set of decoder values to the first memory for storage;
a second single-port memory for storing the second set of decoder values; and
second decoder logic circuitry, coupled to receive results from the first decoder logic circuitry, the second update circuitry for updating one or more of the second set of decoder values responsive to the results from the first decoder logic circuitry, and having an output coupled to present the updated one or more of the second set of decoder values to the second single-port memory for storage;
wherein the second single-port memory is coupled to present one or more of the second set of decoder values to the first decoder logic circuitry;
and wherein the first single-port memory comprises:
an array of memory cells arranged in rows and columns;
peripheral circuitry coupled to the array of memory cells, for writing data to and reading data from a selected memory cell in the array, responsive to a read/write control signal indicating whether a read or write is to be performed; and
logic circuitry for generating and applying to the peripheral circuitry, within a single operating cycle of the first and second decoder logic circuitry, the read/write control signal indicating a read operation in combination with a read memory address during a read portion of the operating cycle, and the read/write control signal indicating a write operation in combination with a write memory address during a write portion of the operating cycle.

20. The decoder circuitry of claim 19, wherein the first decoder logic circuitry comprises:
a first plurality of adders in parallel with one another, each adder receiving a corresponding one of the first set of decoder values, and receiving a corresponding one of the second set of decoder values, each adder for subtracting the one of the first set of decoder values from the one of the second set of decoder values;
parity check update logic, for generating updated ones of the first set of decoder values responsive to the results of the subtractions by the first plurality of adders; and
a second plurality of adders in parallel with one another, each adder receiving a corresponding one of the updated estimate values, and receiving a corresponding one of the results of the subtractions by the first plurality of adders, each adder for adding the one of the updated estimate values and the one of the results of the subtractions.

21. The decoder circuitry of claim 19, wherein the first decoder logic circuitry evaluates a parity check sum corresponding to a Low Density Parity Check (LDPC) code.

22. The decoder circuitry of claim 19, wherein the logic circuitry of the first single-port memory generates the read/write control signal indicating a read operation before generating the read/write control signal indicating a write operation, within the operating cycle.

23. The decoder circuitry of claim 19, wherein the logic circuitry of the first single-port memory generates the read/write control signal indicating a write operation before generating the read/write control signal indicating a read operation, within the operating cycle.

24. An integrated circuit including a receiver function for receiving and decoding encoded digital data, comprising:
a first interface, for receiving communicated signals from a communications facility and presenting, at an output, a digital data stream corresponding to the received signals;
signal processing logic, coupled to the first network interface, for receiving and processing the digital data stream;
a second interface, for communicating processed data corresponding to the digital data stream; and
decoder circuitry, for decoding at least a portion of the digital data stream that is encoded according to an error detection and correction code, the decoder circuitry comprising:
a first single-port memory for storing a first set of decoder values;
first decoder logic circuitry, coupled to receive selected contents of the first memory, for updating one or more of the first set of decoder values responsive to a second set of decoder values, and having an output coupled to present the updated one or more of the first set of decoder values to the first memory for storage;
a second memory for storing the second set of decoder values; and
second decoder logic circuitry, coupled to receive results from the first decoder logic circuitry and to receive input data corresponding to an encoded portion of the digital data stream, the second update circuitry for updating one or more of the second set of decoder values responsive to the results from the first decoder logic circuitry, and having an output coupled to present the updated one or more of the second set of decoder values to the second single-port memory for storage;
wherein the second memory is coupled to present one or more of the second set of decoder values to the first decoder logic circuitry;
and wherein the first single-port memory comprises:
an array of memory cells arranged in rows and columns;
peripheral circuitry coupled to the array of memory cells, for writing data to and reading data from a selected memory cell in the array, responsive to a read/write control signal indicating whether a read or write is to be performed; and
logic circuitry for generating and applying to the peripheral circuitry, within a single operating cycle of the first and second decoder logic circuitry, the read/write control signal indicating a read operation in combination with a read memory address during a read portion of the operating cycle, and the read/write control signal indicating a write operation in combination with a write memory address during a write portion of the operating cycle.

25. The integrated circuit of claim 24, wherein the first decoder logic circuitry comprises:
a first plurality of adders in parallel with one another, each adder receiving a corresponding one of the first set of decoder values, and receiving a corresponding one of the second set of decoder values, each adder for subtracting the one of the first set of decoder values from the one of the second set of decoder values;
parity check update logic, for generating updated ones of the first set of decoder values responsive to the results of the subtractions by the first plurality of adders; and
a second plurality of adders in parallel with one another, each adder receiving a corresponding one of the updated estimate values, and receiving a corresponding one of the results of the subtractions by the first plurality of adders, each adder for adding the one of the updated estimate values and the one of the results of the subtractions.

26. The integrated circuit of claim 24, wherein the first decoder logic circuitry evaluates a parity check sum corresponding to a Low Density Parity Check (LDPC) code.

27. The integrated circuit of claim 24, wherein the logic circuitry of the second single-port memory generates the read/write control signal indicating a read operation before generating the read/write control signal indicating a write operation, within the operating cycle.

28. The integrated circuit of claim 24, wherein the logic circuitry of the second single-port memory generates the read/write control signal indicating a write operation before generating the read/write control signal indicating a read operation, within the operating cycle.
